(19) United States
(12) Patent Application Publication
(10) Pub. No.: US 2019/0288642 A1
(43) Pub. Date: Sep. 19, 2019

(54) I-V CURVE MEASUREMENT DEVICE

(71) Applicant: OMRON Corporation, Kyoto (JP)

(72) Inventors: Makoto OHASHI, Kyoto-shi (JP); Akihiko SANO, Kyoto-shi (JP); Yoshihiko YAMAGUCHI, Kyoto-shi (JP); Tsuyoshi TAKEUCHI, Kyoto-shi (JP)

(73) Assignee: OMRON Corporation, KYOTO (JP)

(21) Appl. No.: 16/248,777

(22) Filed: Jan. 16, 2019

(30) Foreign Application Priority Data
Mar. 14, 2018 (JP) 2018-046539

(51) Int. Cl. H02S 50/10; G01R 19/165

(52) U.S. Cl. CPC H02S 50/10; G01R 19/165

(57) ABSTRACT

The disclosure provides an I-V curve measurement device for providing a user with an I-V curve suitable for judging the state of a solar cell array. The I-V curve measurement device includes a measuring unit for measuring the I-V curve of the solar cell array while lowering an output voltage of the solar cell array and then measuring a short-circuit current of the solar cell array when measurement of the I-V curve is instructed; and an outputting unit for outputting a measurement result of the I-V curve obtained by the measuring unit when the short-circuit current measured by the measuring unit exceeds a predetermined current and outputting information indicating that illuminance is insufficient when the short-circuit current measured by the measuring unit is equal to or less than the predetermined current.

### CROSS-REFERENCE TO RELATED APPLICATION

This application claims the priority benefit of Japan Application No. 2018-046539, filed on Mar. 14, 2018. The entirety of the above-mentioned patent application is hereby incorporated by reference herein and made a part of this specification.

### BACKGROUND

### Technical Field

The disclosure relates to a current-voltage (I-V) curve measurement device for measuring an I-V curve of a solar cell array.

### Description of Related Art

In order to evaluate the state of a solar cell array (presence or absence of the influence of shadow, etc.), the I-V curve of the solar cell array is measured. However, the shape of the I-V curve of the solar cell array changes greatly depending on illuminance (sunshine amount). Also, there are cases in which the state of the solar cell array cannot be accurately determined from the I-V curve measured under low-illuminance condition. Therefore, the I-V curve is usually measured after confirming that there is a certain degree of illuminance using a luminometer or by visual observation. Furthermore, techniques for estimating illuminance (sunshine amount) from the temperature of a solar cell array, short-circuit current, etc. have also been developed (refer to Patent Document 1).

### RELATED ART

### Patent Document

[Patent Document 1] Japanese Laid-open No. 2017-51057

As mentioned above, there are cases in which the state of a solar cell array cannot be accurately determined from the I-V curve measured under low-illuminance condition. Therefore, it is desirable to be able to measure only the I-V curve suitable for judging the state of the solar cell array.

### SUMMARY

In an embodiment of the disclosure, an I-V curve measurement device is provided. The I-V curve measurement device includes a measuring unit for measuring a short-circuit current of a solar cell array when measurement of an I-V curve is instructed; and an outputting unit for outputting a measurement result of the I-V curve of the solar cell array when the short-circuit current measured by the measuring unit exceeds a predetermined current and outputting information indicating that illuminance is insufficient when the short-circuit current measured by the measuring unit is equal to or less than the predetermined current.

Also, in an embodiment of the disclosure, an I-V curve measurement device is provided. The I-V curve measurement device includes a measuring unit for measuring a short-circuit current of a solar cell array when measurement of an I-V curve is instructed; and a measuring/outputting unit for outputting a measurement result of the I-V curve of the solar cell array when the short-circuit current measured by the measuring unit exceeds a predetermined current, monitoring that the short-circuit current of the solar cell array exceeds the predetermined current when the short-circuit current measured by the measuring unit is equal to or less than the predetermined current, and measuring the I-V curve of the solar cell array and outputting the measurement result when the short-circuit current of the solar cell array exceeds the predetermined current.

### BRIEF DESCRIPTION OF THE DRAWINGS

FIG. 1 is an illustration circuit block diagram of a configuration and usage form of an I-V curve measurement device according to an embodiment of the disclosure.

FIG. 2 is a flowchart of an I-V curve measurement process executed by a control unit in an I-V curve measurement device.

FIG. 3A is an illustration diagram of the process of Step S101 of an I-V curve measurement process.

FIG. 3B is an illustration diagram of the process of Step S108 of an I-V curve measurement process.

FIG. 4 is a flowchart for illustrating a modified example of an I-V curve measurement device.

### DESCRIPTION OF THE EMBODIMENTS

The disclosure provides an I-V curve measurement device capable of providing a user with the I-V curve (the measurement result of the I-V curve) suitable for judging the state of the solar cell array.

In an embodiment of the disclosure, an I-V curve measurement device is provided. The I-V curve measurement device includes a measuring unit for measuring a short-circuit current of a solar cell array when measurement of an I-V curve is instructed; and an outputting unit for outputting a measurement result of the I-V curve of the solar cell array when the short-circuit current measured by the measuring unit exceeds a predetermined current and outputting information indicating that illuminance is insufficient when the short-circuit current measured by the measuring unit is equal to or less than the predetermined current.

In other words, this I-V curve measurement device judges whether illuminance at the time of measuring the I-V curve is acceptable (illuminance at a level at which the I-V curve suitable for judging the state of the solar cell array may be obtained) based on the short-circuit current, which has a strong positive correlation with illuminance (sunshine amount), of the solar cell array. Then, the I-V curve measurement device outputs the measurement result of the I-V curve when illuminance at the time of measuring the I-V curve is acceptable, but when illuminance at the time of measuring the I-V curve is not acceptable, information indicating that illuminance is insufficient, instead of the measurement result of the I-V curve, is outputted. Therefore, the user of the I-V curve measurement device can obtain the I-V curve suitable for judging the state of the solar cell array.

In the I-V curve measurement device according to an embodiment of the disclosure, the configuration in which “the measuring unit measures the I-V curve of the solar cell array and then measures the short-circuit current of the solar cell array when measurement of the I-V curve is instructed, and the outputting unit outputs the measurement result of the I-V curve obtained by the measuring unit when the short-circuit current measured by the measuring unit exceeds the predetermined current” may be adopted. The measuring unit in this configuration may measure the I-V curve of the solar cell array while lowering the output voltage of the solar cell array.

Also, in an embodiment of the disclosure, an I-V curve measurement device is provided. The I-V curve measurement device includes a measuring unit for measuring a short-circuit current of a solar cell array when measurement of an I-V curve is instructed; and a measuring/outputting unit for outputting a measurement result of the I-V curve of the solar cell array when the short-circuit current measured by the measuring unit exceeds a predetermined current, monitoring that the short-circuit current of the solar cell array exceeds the predetermined current when the short-circuit current measured by the measuring unit is equal to or less than the predetermined current, and measuring the I-V curve of the solar cell array and outputting the measurement result when the short-circuit current of the solar cell array exceeds the predetermined current.

In other words, this I-V curve measurement device outputs the measurement result of the I-V curve when illuminance at the time of measuring the I-V curve is acceptable, but waits until illuminance reaches an acceptable value, when illuminance at the time of measuring the I-V curve is not acceptable, to measure the I-V curve and output the measurement result. Therefore, the user of the I-V curve measurement device can also obtain the I-V curve suitable for judging the state of the solar cell array.

In the I-V curve measurement device according to an embodiment of the disclosure, the configuration in which “the measuring unit measures the I-V curve of the solar cell array and then measures the short-circuit current of the solar cell array when measurement of the I-V curve is instructed, and the measuring/outputting unit outputs the measurement result of the I-V curve obtained by the measuring unit when the short-circuit current measured by the measuring unit exceeds the predetermined current” or “the measuring unit measures the I-V curve of the solar cell array while lowering an output voltage of the solar cell array, and the measuring/outputting unit measures the I-V curve of the solar cell array while increasing the output voltage of the solar cell array” may be adopted.

According to the I-V curve measurement device of the disclosure, it is possible to provide the user with the I-V curve (the measurement result of the I-V curve) suitable for judging the state of the solar cell array.

Hereinafter, embodiments of the disclosure will be described with reference to the drawings.

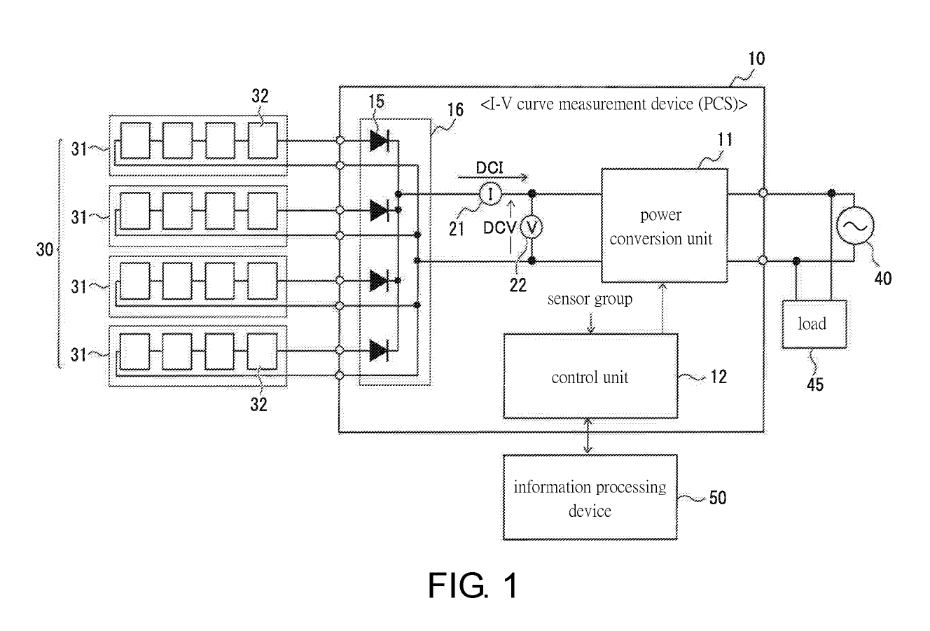

FIG. 1 shows a schematic configuration and usage form of an I-V curve measurement device 10 according to an embodiment of the disclosure.

The I-V curve measurement device 10 according to the embodiment is a so-called power conditioner (PCS).

As shown in the drawing, the I-V curve measurement device 10 (hereinafter also referred to as the measurement device 10) is provided with a plurality of connection terminals (four in the drawing) for connecting strings 31 of a solar cell array 30 respectively. Furthermore, the string 31 is a unit in which a plurality (multiple sheets) of solar cell panels 32 are connected in series.

Also, the measurement device 10 includes a connection circuit 16, a power conversion unit 11, and a control unit 12. The connection circuit 16 is a circuit that connects in parallel the input from each connection terminal via a blocking diode (reverse flow prevention diode) 15 provided for each connection terminal, and outputs it.

The power conversion unit 11 is a unit for converting direct current (DC) power from the connection circuit 16 (that is, power generated by the solar cell array 30) into alternating current (AC) power and supplying the AC power to a load 45 and/or a system 40. The power conversion unit 11 includes a DC/DC converter and a DC/AC inverter. In the measurement device 10, a current sensor 21 for detecting an output current DCI of the solar cell array 30 and a voltage sensor 22 for detecting an output voltage DCV of the solar cell array 30 are provided. Also, in the measurement device 10, sensors (not shown) other than the sensors 21 and 22 are also provided.

The control unit 12 is a unit including a processor (central processing unit (CPU), microcontroller, etc.), a gate driver, a communication interface circuit for communicating with an external device, etc. Outputs of various sensors, including the current sensor 21 and the voltage sensor 22, are inputted into the control unit 12. The control unit 12 performs a normal process and an I-V curve measurement process based on the information from the various sensors.

The normal process performed by the control unit 12 is a process of controlling the power conversion unit 11 so that the maximum power is extracted from the solar cell array 30 and converted into the desired AC power.

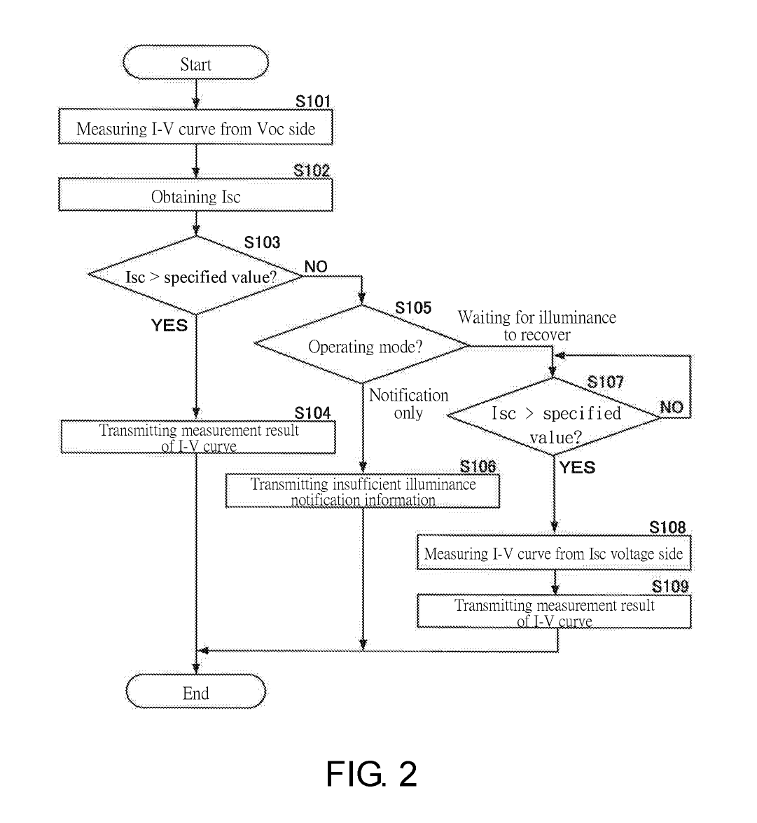

The I-V curve measurement process performed by the control unit 12 is the process of the procedure shown in FIG. 2. The control unit 12 starts this I-V curve measurement process when a measurement of the I-V curve is instructed from an information processing device 50. Furthermore, the information processing device 50 is a device programmed so as to perform various processes for grasping the state of the solar cell array 30 from the I-V curve (the measurement result of the I-V curve) of the solar cell array 30. This information processing device 50 may be a program installed in a general computer for I-V curve analysis, or a device manufactured for a power conditioner, which is the I-V curve measurement device 10.

Hereinafter, the content of the I-V curve measurement process (FIG. 2) will be illustrated.

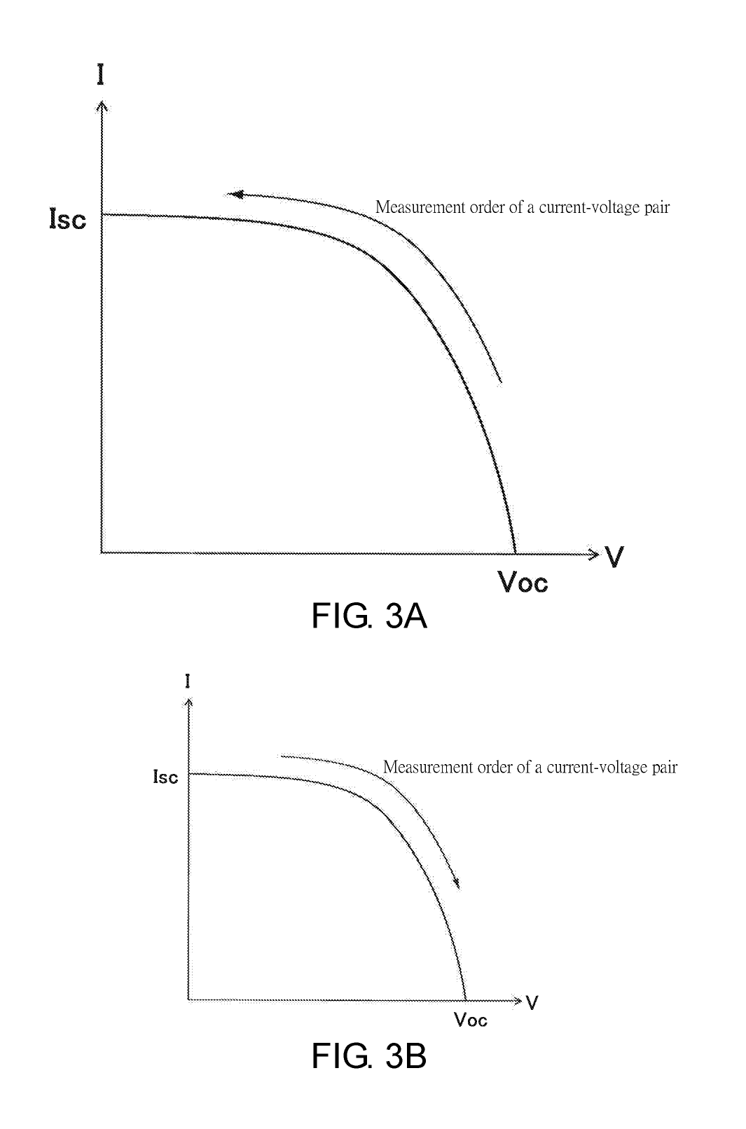

Since the measurement of the I-V curve is instructed, the control unit 12 which started this I-V curve measurement process first measures the I-V curve of the solar cell array 30 from the side of an open-circuit voltage Voc (Step S101). Here, “measuring the I-V curve from the side of the open-circuit voltage Voc” means “measuring a pair of output voltage and output current of the solar cell array 30 from the Voc side” as shown in FIG. 3A. Also, the process actually performed by the control unit 12 in Step S101 is a process of controlling the DC/DC converter in the power conversion unit 11 so that the output voltage of the solar cell array 30 increases to Voc and then decreases; and a process of measuring the pair of output voltage and output current of the solar cell array 30 a plurality of times while the output voltage of the solar cell array 30 is decreasing.

The control unit 12 which has finished the process of Step S101 obtains a short-circuit current Isc of the solar cell array 30 (Step S102). Then, the control unit 12 judges whether the Isc exceeds a specified value (a predetermined current) (Step S103). Here, the specified value is a value predetermined as the minimum value of the Isc value from which the I-V curve suitable for judging the state of the solar cell array may be obtained.

When the Isc exceeds the specified value (Step S103; YES), the control unit 12 transmits the measurement result of the I-V curve obtained by the process of Step S101 to the information processing device 50 (Step S104) and then ends this I-V curve measurement process.

Furthermore, when the Isc is equal to or less than the specified value (Step S103; NO), the control unit 12 judges whether the present operating mode is a notification only mode or an illuminance recovery waiting mode (Step S105). Also, setting (designation) of the operating mode (the notification only mode or the illuminance recovery waiting mode) is performed by a command from the information processing device 50.

When the present operating mode is the notification only mode (Step S105; notification only), the control unit 12 transmits insufficient illuminance notification information indicating that illuminance is insufficient to the information processing device 50 (Step S106). The insufficient illuminance notification information may be any information indicating that illuminance is insufficient based on the information. Accordingly, the insufficient illuminance notification information may be a text message indicating only that illuminance is insufficient or a text message including the Isc obtained in the process of Step S102, or only the Isc. Then, the control unit 12 which has finished the process of Step S106 ends this I-V curve measurement process.

On the other hand, when the present operating mode is the illuminance recovery waiting mode (Step S105; waiting for illuminance recovery), the control unit 12 monitors (on stand-by) the Isc exceeds the specified value (predetermined current) (Step S107). That is, the control unit 12 repeats the processes of measuring the Isc and comparing the measured Isc with the specified value.

When the Isc exceeds the specified value (a predetermined current) (Step S107; YES), the control unit 12 measures the I-V curve of the solar cell array 30 from the short-circuit current-voltage side (Step S108). That is, as shown in FIG. 3B, the control unit 12 performs a process of measuring the pair of output voltage and output current of the solar cell array 30 from the Isc side.

Then, the control unit 12 transmits the measurement result of the I-V curve obtained by the process of Step S108 to the information processing device 50 (Step S109) and then ends the I-V curve measurement process.

As illustrated above, the I-V curve measurement device 10 judges whether illuminance at the time of measuring the I-V curve is acceptable (whether illuminance is at the level at which the I-V curve suitable for judging the state of the solar cell array may be obtained) based on the short-circuit current Isc of the solar cell array 30 having a strong positive correlation with illuminance (sunshine amount). Then, when illuminance at the time of measuring the I-V curve is acceptable, the I-V curve measurement device 10 transmits the measurement result of the I-V curve to the information processing device 50.

On the other hand, when illuminance at the time of measuring the I-V curve is not acceptable, the I-V curve measurement device 10 operating in the notification only mode transmits the insufficient illuminance notification information indicating that illuminance is insufficient, instead of the measurement result of the I-V curve, to the information processing device 50. Also, if illuminance at the time of measuring the I-V curve is not acceptable, the I-V curve measurement device 10 operating in the illuminance recovery waiting mode waits until illuminance reaches an acceptable value, then measures the I-V curve again, and outputs the measurement result to the information processing device 50.

Therefore, the user of the I-V curve measurement device 10 can obtain the I-V curve suitable for judging the state of the solar cell array 30.

### Modified Embodiment

The I-V curve measurement device 10 above may be modified in various ways. For example, the I-V curve measurement process (FIG. 2) may be modified to a process in which the I-V curve of the solar cell array 30 is measured from the side of the open-circuit voltage Voc in Step S108. However, it takes a certain amount of time for the power conversion unit 11 (DC/DC converter), which is in a state for measuring the short-circuit current Isc, to shift to a state in which the I-V curve of the solar cell array 30 can be measured from the side of the open-circuit voltage Voc. Therefore, by adopting the procedure above, the time until the end of the process may be shortened.

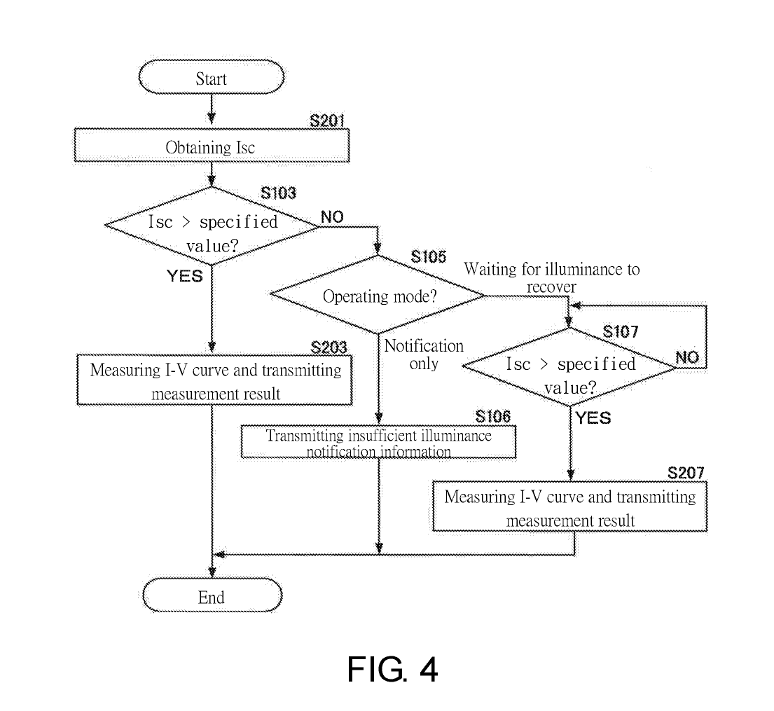

Furthermore, the I-V curve measurement process (FIG. 2) may be modified to the I-V curve measurement process of the procedure shown in FIG. 4. That is, the I-V curve measurement process may be modified to a process in which the short-circuit current Isc is obtained without measuring the I-V curve (Step S201); and when the Isc is equal to or more than the specified value (Step S103; YES), the I-V curve of the solar cell array 30 is measured and transmitted to the information processing device 50 (Step S203). The processes in Steps S203 and S207 of the I-V curve measurement process are preferably for measuring the I-V curve from the side of the short-circuit current Isc, but may be for measuring the I-V curve from the side of the open-circuit voltage Voc.

Furthermore, although the I-V curve measurement device 10 above is a PCS, the I-V curve measurement device 10 may be modified into a device for measuring the I-V curve (a device referred to as an I-V curve tracer, etc.). The I-V curve measurement device 10 may be modified into a device which may also designate the operating mode when instructing an I-V curve measurement. Also, the I-V curve measurement device 10 may be modified into a device operating by an instruction from a remote place (an instruction inputted via a communication network).

The I-V curve measurement device 10 may be modified into a device which, when detecting that the Isc is less than the specified value during operation in the illuminance recovery waiting mode (Step S103: NO and S105: waiting for illuminance recovery), starts the processes in Step S107 and the steps thereafter after sending an insufficient illuminance notification information to the information processing device 50. Also, the I-V curve measurement device 10 may be modified into a device for starting the I-V curve measurement process or a device for displaying the measurement result of the I-V curve when an operation panel, etc. provided in the I-V curve measurement device 10 is operated.

### APPENDIX

(1) An I-V curve measurement device (10), comprising:

a measuring unit (11, 12) for measuring a short-circuit current of a solar cell array (30) when measurement of an I-V curve is instructed; and

an outputting unit (12) for outputting a measurement result of the I-V curve of the solar cell array (30) when the short-circuit current measured by the measuring unit (11, 12) exceeds a predetermined current and outputting information indicating that illuminance is insufficient when the short-circuit current measured by the measuring unit is equal to or less than the predetermined current.

(2) An I-V curve measurement device (10), comprising:

a measuring unit (11, 12) for measuring a short-circuit current of a solar cell array (30) when measurement of an I-V curve is instructed; and

a measuring/outputting unit (11, 12) for outputting a measurement result of the I-V curve of the solar cell array (30) when the short-circuit current measured by the measuring unit (11, 12) exceeds a predetermined current, monitoring that the short-circuit current of the solar cell array (30) exceeds the predetermined current when the short-circuit current measured by the measuring unit (11, 12) is equal to or less than the predetermined current, and measuring the I-V curve of the solar cell array (30) and outputting the measurement result when the short-circuit current of the solar cell array (30) exceeds the predetermined current.

What is claimed is:

1. An I-V curve measurement device, comprising:
a measuring unit for measuring a short-circuit current of a solar cell array when measurement of an I-V curve is instructed; and
an outputting unit for outputting a measurement result of the I-V curve of the solar cell array when the short-circuit current measured by the measuring unit exceeds a predetermined current, and outputting information indicating that illuminance is insufficient when the short-circuit current measured by the measuring unit is equal to or less than the predetermined current.

2. The I-V curve measurement device according to claim 1, wherein
the measuring unit measures the I-V curve of the solar cell array and then measures the short-circuit current of the solar cell array when measurement of the I-V curve is instructed, and
the outputting unit outputs the measurement result of the I-V curve obtained by the measuring unit when the short-circuit current measured by the measuring unit exceeds the predetermined current.

3. The I-V curve measurement device according to claim 1, wherein
the measuring unit measures the I-V curve of the solar cell array while lowering an output voltage of the solar cell array.

4. The I-V curve measurement device according to claim 2, wherein
the measuring unit measures the I-V curve of the solar cell array while lowering an output voltage of the solar cell array.

5. An I-V curve measurement device, comprising:
a measuring unit for measuring a short-circuit current of a solar cell array when measurement of an I-V curve is instructed; and
a measuring/outputting unit for outputting a measurement result of the I-V curve of the solar cell array when the short-circuit current measured by the measuring unit exceeds a predetermined current, monitoring that the short-circuit current of the solar cell array exceeds the predetermined current when the short-circuit current measured by the measuring unit is equal to or less than the predetermined current, and measuring the I-V curve of the solar cell array and outputting the measurement result when the short-circuit current of the solar cell array exceeds the predetermined current.

6. The I-V curve measurement device according to claim 5, wherein
the measuring unit measures the I-V curve of the solar cell array and then measures the short-circuit current of the solar cell array when measurement of the I-V curve is instructed, and
the measuring/outputting unit outputs the measurement result of the I-V curve obtained by the measuring unit when the short-circuit current measured by the measuring unit exceeds the predetermined current.

7. The I-V curve measurement device according to claim 5, wherein
the measuring unit measures the I-V curve of the solar cell array while lowering an output voltage of the solar cell array, and
the measuring/outputting unit measures the I-V curve of the solar cell array while increasing the output voltage of the solar cell array.

8. The I-V curve measurement device according to claim 6, wherein
the measuring unit measures the I-V curve of the solar cell array while lowering an output voltage of the solar cell array, and
the measuring/outputting unit measures the I-V curve of the solar cell array while increasing the output voltage of the solar cell array.

9. The I-V curve measurement device according to claim 5, wherein
the I-V curve measurement device has a first operating mode and a second operating mode as operating modes,
the measuring/outputting unit functions when the operating mode of the I-V curve measurement device is the first operating mode, and
the I-V curve measurement device further comprises a second measuring/outputting unit that functions when the operating mode of the I-V curve measurement device is the second operating mode, and the second measuring/outputting unit outputs the measurement result of the I-V curve of the solar cell array when the short-circuit current measured by the measuring unit exceeds the predetermined current and outputs information indicating that illuminance is insufficient when the short-circuit current measured by the measuring unit is equal to or less than the predetermined current.

10. The I-V curve measurement device according to claim 6, wherein
the I-V curve measurement device has a first operating mode and a second operating mode as operating modes,
the measuring/outputting unit functions when the operating mode of the I-V curve measurement device is the first operating mode, and
the I-V curve measurement device further comprises a second measuring/outputting unit that functions when the operating mode of the I-V curve measurement device is the second operating mode, and the second measuring/outputting unit outputs the measurement result of the I-V curve of the solar cell array when the short-circuit current measured by the measuring unit exceeds the predetermined current and outputs information indicating that illuminance is insufficient when the short-circuit current measured by the measuring unit is equal to or less than the predetermined current.

11. The I-V curve measurement device according to claim 7, wherein
the I-V curve measurement device has a first operating mode and a second operating mode as operating modes,
the measuring/outputting unit functions when the operating mode of the I-V curve measurement device is the first operating mode, and
the I-V curve measurement device further comprises a second measuring/outputting unit that functions when the operating mode of the I-V curve measurement device is the second operating mode, and the second measuring/outputting unit outputs the measurement result of the I-V curve of the solar cell array when the short-circuit current measured by the measuring unit exceeds the predetermined current and outputs information indicating that illuminance is insufficient when the short-circuit current measured by the measuring unit is equal to or less than the predetermined current.
